(19) United States
(12) Patent Application Publication
(10) Pub. No.: US 2012/0180871 A1
(43) Pub. Date: Jul. 19, 2012

(54) NEUTRAL MIXED LIGAND TRANSITION METAL COMPLEXES AS ACTIVE MATERIALS IN SOLID-STATE ORGANIC PHOTOVOLTAIC DEVICES

(75) Inventor: Mohammad A. Omary, Denton, TX (US)

(73) Assignee: UNIVERSITY OF NORTH TEXAS, Denton, TX (US)

(21) Appl. No.: 13/499,604

(22) PCT Filed: Oct. 1, 2010
(86) PCT No.: PCT/US10/51218

§ 371 Date: Mar. 30, 2012

Related U.S. Application Data
(60) Provisional application No. 61/247,878, filed on Oct. 1, 2009.

(51) Int. Cl. H01L 51/46; C07F 15/00

(52) U.S. Cl. 136/263; 546/2; 546/10

(57) ABSTRACT

The present invention describes novel “black absorbers” comprising mixed ligand metal-organic complexes to be used in OPVs. The invention describes three representative metal-organic dyes that exhibit strong absorptions spanning the entire UV/Vis portion of the solar light and, in the some cases, well within the NIR. The invention further describes the fabrication of an OPV device by co-doping P1 in a standard polymer/fullerene matrix commonly used in a bulk heterojunction device structure.

### TECHNICAL FIELD OF THE INVENTION

The present invention relates in general to the field of organic photovoltaics (OPVs), and more particularly to development of a metal-organic dye with greater absorptive capacity for solar radiations to be used in OPVs.

### BACKGROUND OF THE INVENTION

Without limiting the scope of the invention, its background is described in connection with the organic photovoltaic devices and associated components.

U.S. Pat. No. 6,657,378 issued to Forrest and Yakimov, 2003 describes organic photosensitive optoelectronic devices. The organic-based photosensitive optoelectronic devices of the '378 patent have greatly improved efficiencies, comprising of multiple stacked subcells in series between an anode layer and a cathode. Each subcell comprises an electron donor layer, and an electron acceptor layer in contact with the electron donor layer. The subcells are separated by an electron-hole recombination zone. Advantageously, the device also includes one or more exciton blocking layers (EBL) and a cathode smoothing layer.

U.S. Pat. No. 6,051,702 issued to Bird et al. (2000) relates to improved phthalocyanine compounds (Pc's) used as dyes for applications as solar organic photovoltaic (OPV) materials and as electrophotographic (Xerographic) organic photoconductor (OPC) materials.

United States Patent Publication No. 20090133752 (Yu et al., 2009) relates to a method of fabricating an organic photovoltaic device with improved power conversion efficiency by reducing lateral contribution of series resistance between subcells through active area partitioning by introducing a patterned structure of insulating partitioning walls inside the device. According to the method of the present invention, each subcell works independently, there is no interference phenomenon against the current output of each subcells. The method described in the invention can be effectively used in the fabrication and development of a next-generation large area organic thin layer photovoltaic cell device.

### SUMMARY OF THE INVENTION

The present invention describes novel mixed ligand metal-organic complexes for use in OPV devices. The novel materials of the present invention have superior absorptive capacities in entire UV/Vis portion of the solar light and in some cases well within the NIR region.

The present invention describes in one embodiment a mixed ligand metal-organic complex of formula (I):

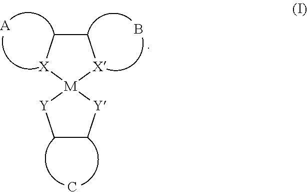

wherein, M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; A is a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous; B is a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous; and C is an aromatic ring, a substituted benzene, a phenyl group, a keto group, a thioamide group, or a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous. In one aspect of the present invention the complex absorbs an ultraviolet radiation, a visible radiation, and a near-infrared radiation. In another aspect the complex is contained in an organic heterojunction separating an anode and a cathode of a multi-layer organic photovoltaic (OPV) device; wherein the heterojunction comprises an electron donor layer, in contact with an electron acceptor layer. In yet another aspect the complex donates or accepts one or more electrons.

In specific aspects the complex comprises Ru(phen)₂(bdt), wherein phen=1,10-phenanthroline and bdt=1,2-benzenedithiolate; Pt(dmecbpy)(bdt), wherein dmecbpy=4,4′-di-methoxyester-2,2′-bipyridine and bdt=1,2-benzenedithiolate; and {Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone.

In another embodiment the present invention is a multi-layer organic photovoltaic device comprising: an anode; a cathode; and an organic heterojunction separating the anode and the cathode, wherein the heterojunction comprises an electron donor layer, in contact with an electron acceptor layer, wherein the organic heterojunction contains a comprises a mixed ligand metal-organic complex of formula (I):

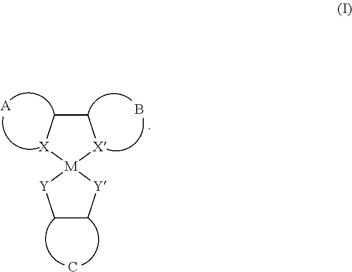

In formula (I) M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; A is a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous; B is a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous; and C is an aromatic ring, a substituted benzene, a phenyl group, a keto group, a thioamide group, or a heterocyclic ring structure selected from a group consisting of a 3-membered, 4-membered, 5-membered, 6-membered, and 7-membered heterocyclic compounds; wherein the heterocyclic compounds comprise one or more hetero atoms selected from a group consisting of nitrogen, oxygen, sulfur, arsenic and phosphorous.

The anode of the organic photovoltaic device of the present invention comprises, metals, alloys, ITO, conducting polymers, or any combinations thereof and the cathode comprises metals selected from a group consisting of Fe, Al, Mg, Mn, Ni, and Ca. In other aspects the mixed ligand metal-organic complex donates or accepts one or more electrons and absorbs an ultraviolet radiation, a visible radiation, and a near-infrared radiation.

In yet another embodiment the present invention describes a mixed ligand metal-organic complex of formula (II):

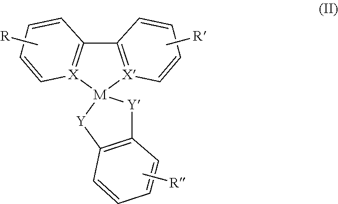

wherein, M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; R is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; R′ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and R″ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group.

In related aspects the complex donates or accepts one or more electrons and absorbs an ultraviolet radiation, a visible radiation, and a near-infrared radiation. In one aspect the complex is contained in an organic heterojunction separating an anode and a cathode of a multi-layer organic photovoltaic (OPV) device; wherein the heterojunction comprises an electron donor layer, in contact with an electron acceptor layer. The complex comprises Ru(phen)₂(bdt), wherein phen=1,10-phenanthroline and bdt=1,2-benzenedithiolate, Pt(dmecbpy)(bdt), wherein dmecbpy=4,4′-di-methoxyester-2,2′-bipyridine and bdt=1,2-benzenedithiolate, and {Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone.

In one embodiment the present invention is a multi-layer organic photovoltaic device comprising: an anode; a cathode; an and organic heterojunction separating the anode and the cathode; wherein the heterojunction comprises an electron donor layer, in contact with an electron acceptor layer; wherein the organic heterojunction contains a comprises a mixed ligand metal-organic complex of formula (II):

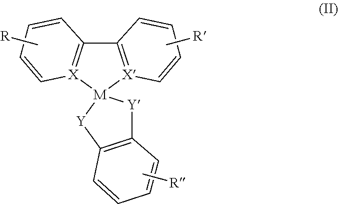

wherein, M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; R is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; R′ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and R″ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group.

In another embodiment the present invention describes a mixed ligand metal-organic complex of formula (III):

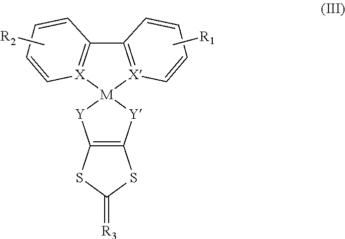

wherein, M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; R₁ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; R₂ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and R₃ is independently selected from a carbon, an oxygen, a nitrogen, or a sulfur.

In one aspect the complex absorbs an ultraviolet radiation, a visible radiation, and a near-infrared radiation. In another aspect the complex is contained in an organic heterojunction separating an anode and a cathode of a multi-layer organic photovoltaic (OPV) device; wherein the heterojunction comprises an electron donor layer, in contact with an electron acceptor layer. In yet another aspect the complex donates or accepts one or more electrons. In various aspects the complex comprises: (i) Ru(phen)₂(bdt), wherein phen=1,10-phenanthroline and bdt=1,2-benzenedithiolate, (ii) Pt(dmecbpy)(bdt), wherein dmecbpy=4,4′-di-methoxyester-2,2′-bipyridine and bdt=1,2-benzenedithiolate, and (iii) {Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone.

In yet another embodiment the present invention is a multi-layer organic photovoltaic device comprising: an anode; a cathode; and an organic heterojunction separating the anode and the cathode; wherein the heterojunction comprises an electron donor layer, in contact with an electron acceptor layer; wherein the organic heterojunction contains a comprises a mixed ligand metal-organic complex of formula (III):

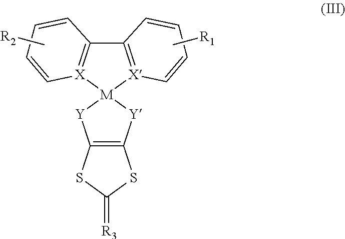

wherein, M is a metal with a d⁸ electronic configuration selected from a group consisting of Pt, Pd, Ni, Fe, Ru, Os, Co, Rh, and Ir; X and X′ are one or more first ligand donor atoms, selected from a group consisting of N, P, As, and Sb; Y and Y′ are one or more second ligand donor atom selected from a group consisting of S, Cl, O, F, and Br; R₁ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; R₂ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and R₃ is independently selected from a carbon, an oxygen, a nitrogen, or a sulfur.

The present invention in one embodiment describes a mixed ligand metal-organic complex of

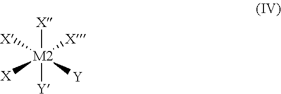

wherein, M2 is a metal with a d⁶ electronic configuration selected from a group consisting of Fe, Ru, Os, Co, Rh, Ir, Pt, Pd, and Ni; X, X, X′, and X′″ are one or more neutral ligand donor atoms, selected from a group consisting of N, P, As, and Sb; and Y and Y′ are one or more anionic ligand donor atom selected from a group consisting of S, Cl, O, F, and Br. In one aspect the complex absorbs an ultraviolet radiation, a visible radiation, and a near-infrared radiation. In another aspect the complex is contained in an organic heterojunction separating an anode and a cathode of a multi-layer organic photovoltaic (OPV) device; wherein the heterojunction comprises an electron donor layer, in contact with an electron acceptor layer. In yet another aspect the complex donates or accepts one or more electrons.

The present invention in another embodiment further describes a multi-layer organic photovoltaic device comprising: an anode; a cathode; and an organic heterojunction separating the anode and the cathode; wherein the heterojunction comprises an electron donor layer, in contact with an electron acceptor layer; wherein the organic heterojunction contains a comprises a mixed ligand metal-organic complex of formula (IV):

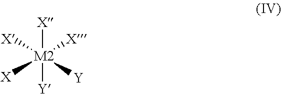

wherein, M2 is a metal with a d⁶ electronic configuration selected from a group consisting of, Fe, Ru, Os, Co, Rh, Ir, Pt, Pd, and Ni; X, X, X′, and X′″ are one or more neutral ligand donor atoms, selected from a group consisting of N, P, As, and Sb; and Y and Y′ are one or more anionic ligand donor atoms selected from a group consisting of S, Cl, O, F, and Br.

In one aspect of the device of the present invention the anode comprises, metals, alloys, ITO, conducting polymers, or any combinations thereof and the cathode comprises metals selected from a group consisting of Fe, Al, Mg, Mn, Ni, and Ca. In another aspect the mixed ligand metal-organic complex absorbs an ultraviolet radiation, a visible radiation, and a near-infrared radiation. In yet another aspect of the device of the present invention the mixed ligand metal-organic complex donates or accepts one or more electrons.

In one embodiment the present invention discloses a mixed ligand metal-organic complex of formula (V). The complex describes donates or accepts one or more electrons and is capable of absorption of an ultraviolet radiation, a visible radiation, and a near-infrared radiation and is contained in an organic heterojunction separating an anode and a cathode of a multi-layer organic photovoltaic (OPV) device, wherein the heterojunction comprises an electron donor layer, in contact with an electron acceptor layer.

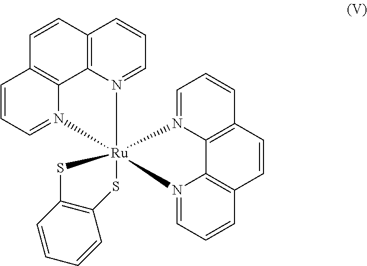

In another embodiment the present invention relates to a multi-layer organic photovoltaic device comprising: an anode; a cathode; and an organic heterojunction separating the anode and the cathode; wherein the heterojunction comprises an electron donor layer, in contact with an electron acceptor layer; wherein the organic heterojunction contains a comprises a mixed ligand metal-organic complex of formula (V):

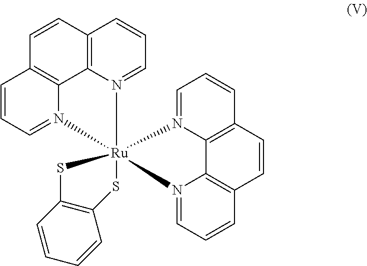

In yet another embodiment a mixed ligand metal-organic complex of formula (VI) is described in the instant invention. The complex absorbs an ultraviolet radiation, a visible radiation, and a near-infrared radiation and donates or accepts one or more electrons. The complex is contained in an organic heterojunction separating an anode and a cathode of a multi-layer organic photovoltaic (OPV) device, wherein the heterojunction comprises an electron donor layer, in contact with an electron acceptor layer.

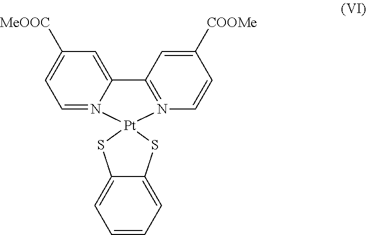

In one embodiment the multi-layer organic photovoltaic device comprises an anode; a cathode; and an organic heterojunction separating the anode and the cathode; wherein the heterojunction comprises an electron donor layer, in contact with an electron acceptor layer; wherein the organic heterojunction contains a comprises a mixed ligand metal-organic complex of formula (VI):

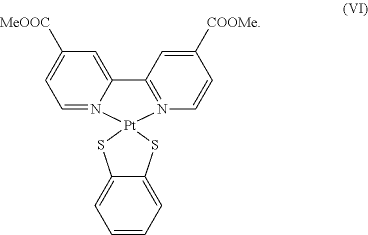

The present invention describes a mixed ligand metal-organic complex of formula (VII):

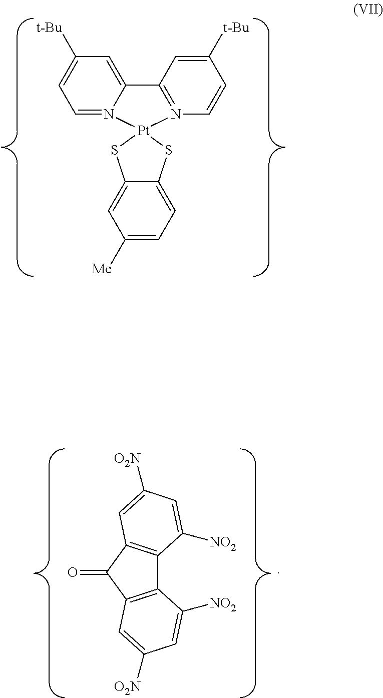

Complex (VII) absorbs an ultraviolet radiation, a visible radiation, and a near-infrared radiation and donates or accepts one or more electrons. Complex (VII) is contained in an organic heterojunction separating an anode and a cathode of a multi-layer organic photovoltaic (OPV) device, wherein the heterojunction comprises an electron donor layer, in contact with an electron acceptor layer.

The present invention in one embodiment discloses a multi-layer organic photovoltaic device comprising: an anode; a cathode; and an organic heterojunction separating the anode and the cathode; wherein the heterojunction comprises an electron donor layer, in contact with an electron acceptor layer; wherein the organic heterojunction contains a comprises a mixed ligand metal-organic complex of formula (VII):

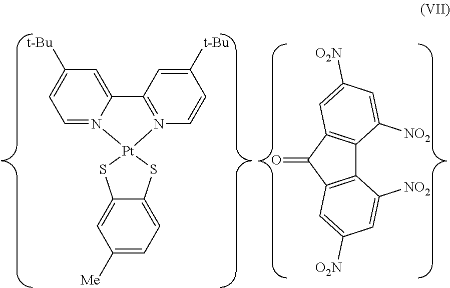

### BRIEF DESCRIPTION OF THE DRAWINGS

For a more complete understanding of the features and advantages of the present invention, reference is now made to the detailed description of the invention along with the accompanying figures and in which:

FIG. 1A shows the absorption spectra of solid films of the three representative embodiments P1, R1, and P2, of the present invention in comparison with P3HT and CuPc, two common light-absorbing materials used in organic photovoltaics technology;

FIG. 1B shows the chemical structures of the three representative embodiments P1, R1, and P2, the absorption spectra of which are shown in FIG. 1A;

FIG. 2A is a plot of the photoconductivity of a 20-nm thin film of P1 versus V at constant λ;

FIG. 2B is a plot of the photoconductivity of a 20-nm thin film of P1 versus λ (200-710 nm) at constant V (16 mV);

FIG. 3A is the normalized absorption spectra of solutions of several representative embodiments of the present invention;

FIG. 3B is the absorption spectra of solutions of different concentrations of the representative embodiment P1 with its absorption coefficients labeled (bottom). Note that the absorption edge of the P1 embodiment in this spectrum can be red-shifted to longer wavelengths and that its strong absorptions can become more uniformly strong across the UV/Vis region for the solid-state form of this material (FIG. 1A);

FIG. 4 shows the X-ray structure for single crystals of the representative embodiment P1. The Pt—Pt distance is 3.5185(6) A and the inter-plane distance is 3.399 Å;

FIG. 5 shows the results of the thermogravimetric analysis (TGA) for a powder of the embodiment P1. Note the thermal stability up to ˜300° C.;

FIG. 6 shows the cyclic voltammograms for the representative embodiment P1;

FIG. 7A shows the absorption spectra for solution mixtures of P1 doped in the P3HT polymer with and without filtration prior to thin-film processing from dichloromethane;

FIG. 7B shows the absorption spectra for solution mixtures of P1 doped in the P3HT polymer with and without filtration prior to thin-film processing from chloroform;

FIG. 8A shows the OPV data of the photocurrent action spectrum for a bulk heterojunction device based on a doped thin film of P1 in a polymer/fullerene matrix;

FIG. 8B shows the OPV data of the photocurrent action spectrum for a bulk heterojunction device of a control without the P1 dye (right). The additional absorptions (e.g., the ones extending beyond 750 nm) are due to the P1 sensitizer;

FIG. 9 shows the chemical structures of prototype embodiments of the present invention. A hierarchy is shown from root structures at higher levels to representative derivative embodiments at lower levels; and

FIG. 10 is an example showing the design of thin-film OPVs by vacuum evaporation of active materials.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The present invention describes novel “black absorbers” to be used in OPVs. The invention describes three representative metal-organic dyes R1, P1, and P2 exhibiting strong absorptions (10⁴-10⁵ cm⁻¹) that span the entire UV/Vis portion of the AM0 (or AM1.5) solar light and, in the case of P2, well within the NIR (up to ˜1200 nm at half maximum).

The disclosure further describes the fabrication of an OPV device by co-doping P1 in a standard polymer/fullerene matrix commonly used in a bulk heterojunction device structure. The black absorbers of the present invention have other advantages over the materials currently used in OPVs including but not limited to significant hole conductivity, thermal stability, reversible oxidation and reduction processes, and thin-film formation.

The world's fossil fuel consumption is 13 trillion watts (Terawatts, TW) of power per year. US consumes 25% of world's consumption, 40% of which is converted to electricity. A reduction in consumption by ˜10% roughly translates to 276 million tons less of carbon emission and a $120B savings to consumer. The sun deposits 120,000 TW of energy a year, however the current state of solar energy utilization is unacceptable. While solar cell efficiencies have reached 20-30% for silicon and III-V inorganic semiconductors like gallium arsenide, the exorbitant cost of crystalline materials and device fabrication plus environmental hazards are inherently prohibitive to adopt such technologies as long-term energy solutions.

There are four main solar cell types: 1) Silicon or germanium (crystalline and amorphous), 2) Inorganic semiconductor (most prominently III-V semiconductors such as GaAs), 3) Dye—sensitized solar cells (DSSCs, organics; solution based), and 4) Organic photovoltaics (OPVs, thin film based).

Silicon and inorganic solar cells have 20-40% efficiencies but are too expensive to manufacture practical devices on large areas and in addition are not very “green”. Out of the four types listed there are two general kinds of organic solar cell technologies being used: OPVs based on solid-state solar cells with thin film processing of active materials, and DSSCs based on suspensions of oxide nanoparticles tethering a dye molecule in an aqueous or organic solvent (typically acetonitrile). DSSCs have 11% efficiencies but are expensive, corrosive, unstable, and not “green”. Organic solar cells, in contrast, have the potential to provide low-cost, eco-friendly photovoltaic technologies to replace fossil fuel. OPVs can be inexpensive, light-weight, large area, “flexible”, and “green” but only ˜5% efficiencies so far (bad in IR, which represents >50% of solar energy; even UV/Vis not great and can be greatly improved).

This present invention pertains to OPVs. The fabrication of OPV devices is typically achieved by vacuum sublimation of small molecules or solution casting (e.g., spin coating or inkjet printing) of polymers or highly-soluble small molecules to attain single or multiple thin films between a transparent anode and a reflective cathode.

Widespread use of OPVs can provide a lot of benefits to the traditional customer including low cost materials and fabrication methods resulting in cheaper products, flexible devices and functionalization of nontraditional surfaces and expanding solar cell applications like solar car roof, solar shingles, and electronics. Advantages for the military customer include portable solar cells for field deployed systems, flexible cells can be incorporated into uniforms for power to, and integration with other flexible electronics, camouflaged solar tents, etc.

The working principle of an OPV device relies on four processes: (i) light absorption by a donor molecule, (ii) exciton diffusion within the donor layer, (iii) charge transfer to an acceptor molecule usually in an adjacent layer, and (iv) charge collection at the electrodes. The photovoltaic materials developed and described in the present invention possess favorable properties for all these processes.

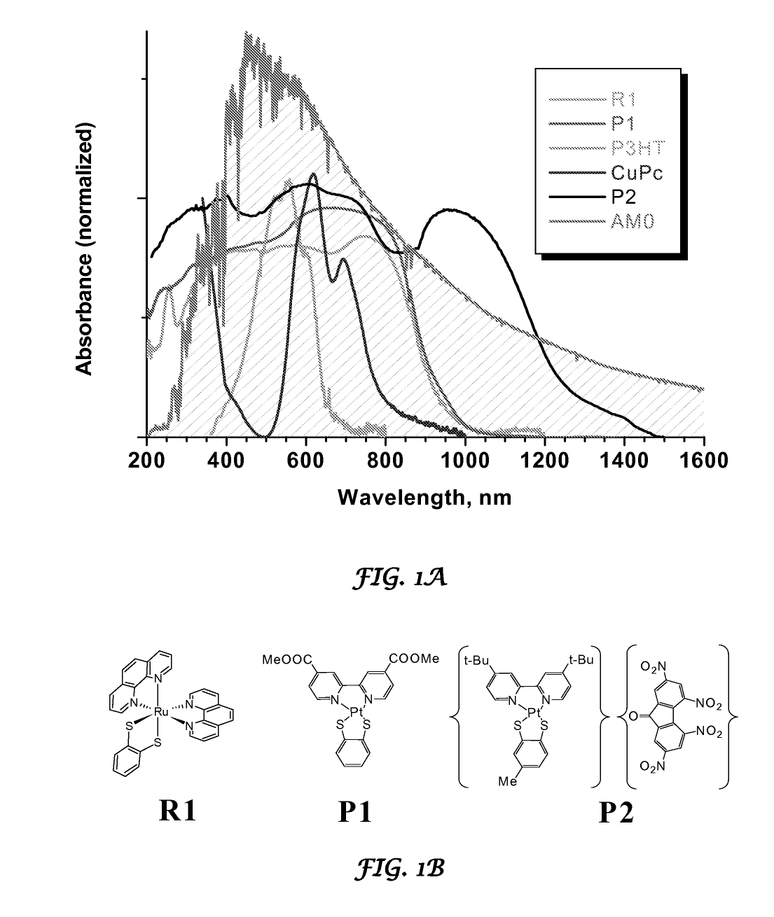

More than 50% of the solar radiation occurs at wavelengths >750 nm. Yet, this spectral region is notoriously excluded from the absorption range of organic dyes typically used in OPVs such as poly(3-hexyl)thiophene (P3HT) and copper phthalocyanine (CuPc), the prototypical light-absorbing materials used in polymer and small-molecule OPVs, respectively. FIG. 1A shows the solid-state absorption spectra of these conventional materials along with several novel metal-organic OPV materials constituting representative embodiments of the present invention. The spectra are overlaid with the AM0 solar light. FIG. 1A highlights the major problem with P3HT- or phthalocyanine-based organic solar cells: the poor overlap of the absorptions of these chromophores with significant portions of the UV/Vis/NIR regions of the solar radiation makes it clear why their peak device efficiencies continue to dwell around ˜5% or lower (Thompson and Frechet, 2008; Peumans et al., 2003).

The situation is dramatically different with novel “black absorbers” of the present invention, as illustrated by absorptions of the representative metal-organic dyes R1, P1, and P2 shown in FIG. 1A. The chemical structures of the representative metal-organic dyes of the present invention R1, P1 and P2 are depicted in FIG. 1B. As shown in FIG. 1B, R1 comprises Ru(phen)₂(bdt), wherein phen=1,10-phenanthroline and bdt=1,2-benzenedithiolate, P1 comprises Pt(dmecbpy)(bdt), wherein dmecbpy=4,4′-di-methoxyester-2,2′-bipyridine and bdt=1,2-benzenedithiolate, and P2 comprises={Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone. All the three materials exhibit strong absorptions (10⁴-10⁵ cm⁻¹) that span the entire UV/Vis portion of the AM0 (or AM1.5) solar light and, in the case of P2, well within the NIR (up to ˜1200 nm at half maximum).

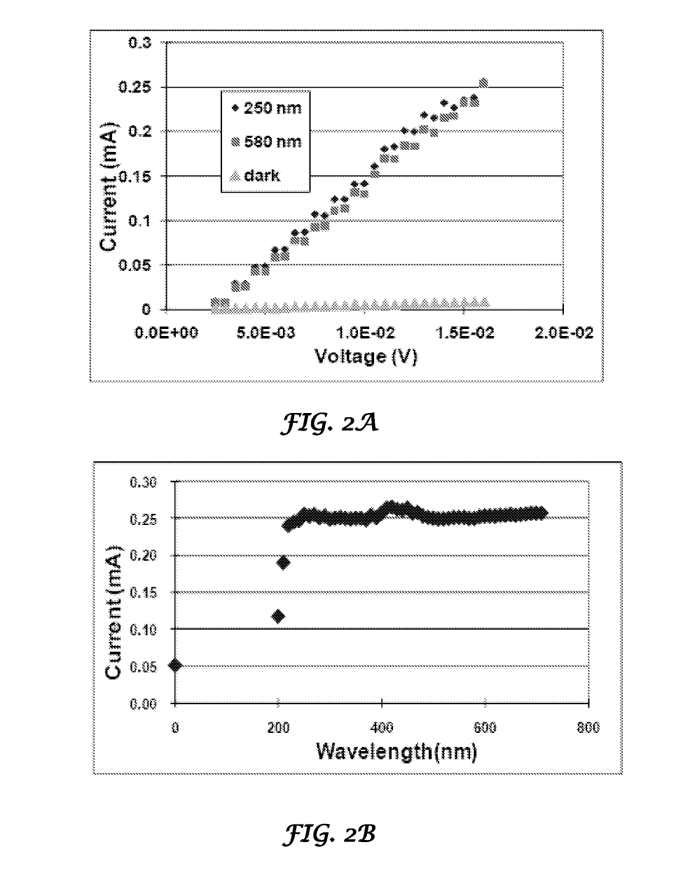

The inventors further validated the usefulness of the black absorbers in OPVs. The photoconductivity data in FIGS. 2A and 2B show a significant photocurrent of ˜0.26 mA at 0.016 V from a 20-nm thin film of this material deposited on a small pixel area (16.2 mm²), giving rise to a photocurrent density of 1.6 mA/cm² under relatively weak lamp irradiation of 15 W. This photocurrent value remained essentially constant in the 220-710 nm range that was tested by the inventors across the UV/Vis region after an initial increase in the 200-220 nm range, consistent with the solid diffuse reflectance spectra. This demonstrated that the embodiment material of the present invention can sensitize a wide range of photon energies within the UV/Vis/NIR.

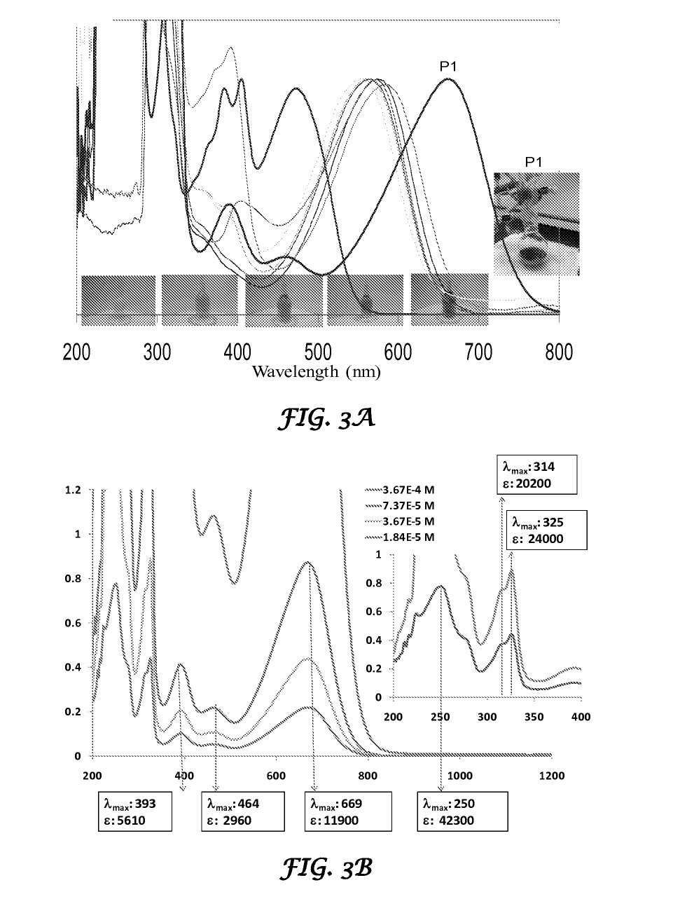

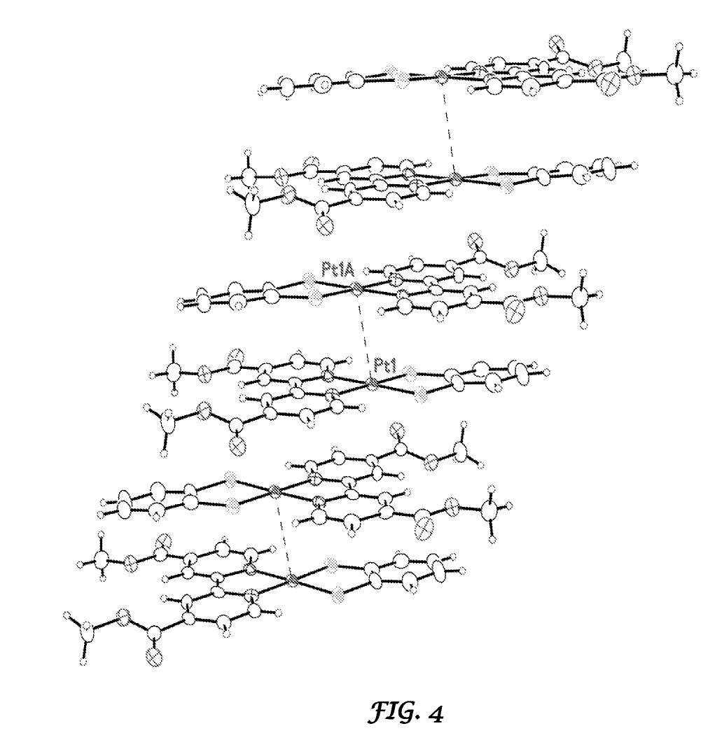

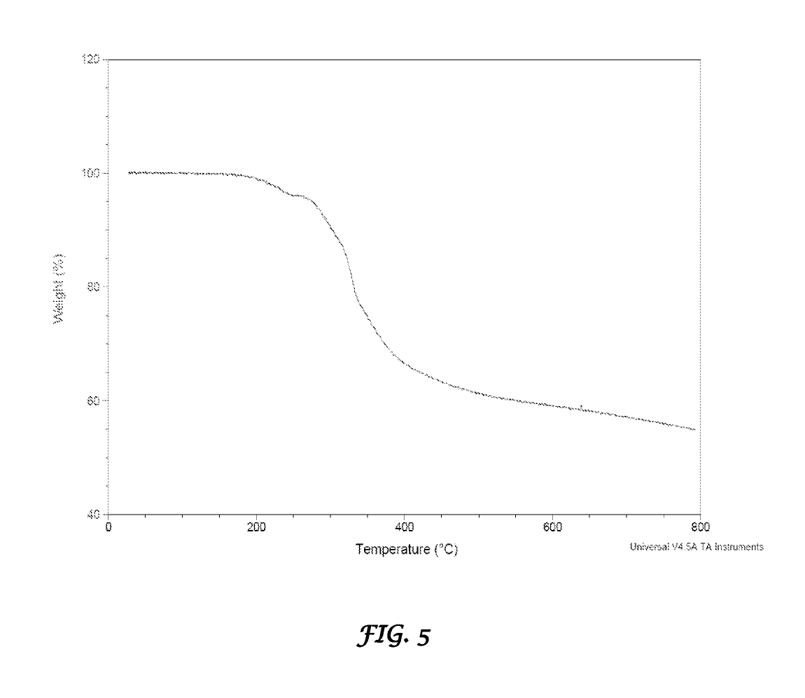

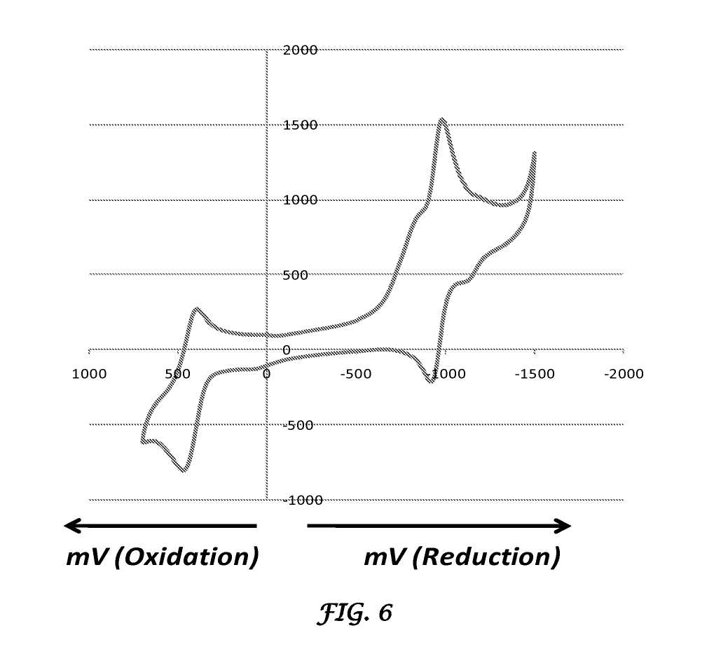

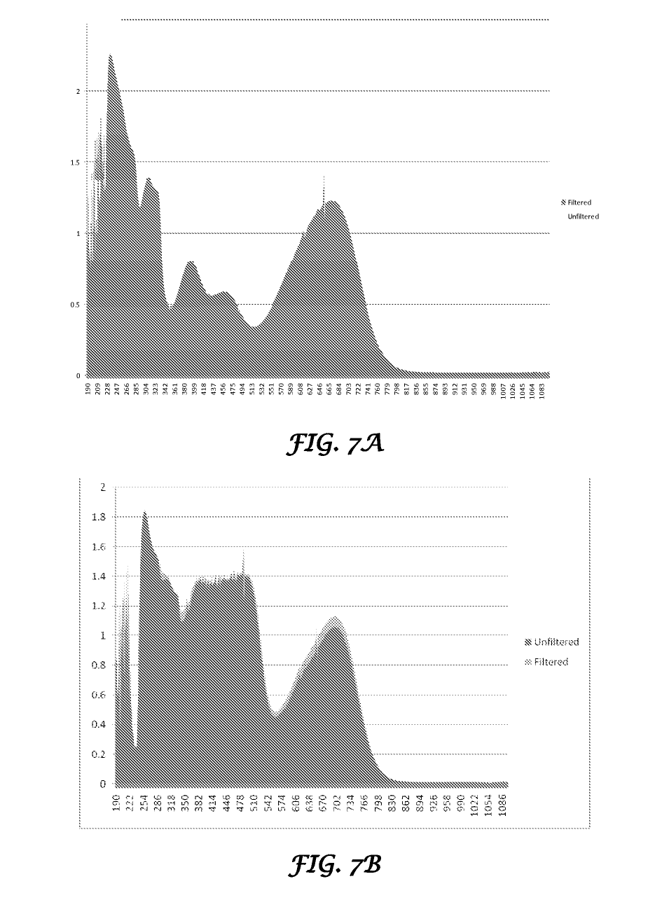

Further desirable properties of the black absorbers that represent the embodiments of the present invention for OPV use include the following: (i) significant hole conductivity of the materials; this includes significant red shift in the solid-state vs. solution absorption (e.g., for P1 in FIG. 1B versus FIG. 3A) and strong packing of molecules as revealed by single crystal X-ray diffraction (FIG. 4), (ii) thermal stability of multiple representatives up to ˜300° C. in air, as revealed by TGA analysis (FIG. 5), (iii) reversible oxidation and reduction processes at suitable potentials for charge separation upon electron transfer to typical OPV acceptor species (FIG. 6), and (iv) thin-film formation, verified by vacuum evaporation. The data shown in FIGS. 2A and 2B data is for a vacuum-evaporated thin film of the material and the inventors have also verified the sublimation ability of multiple other representative embodiments. Most embodiments of the present invention are amenable to solution processing by two means: either direct processing of highly-soluble embodiments or doping the embodiment in a polymer matrix. FIG. 7 shows an example for the latter.

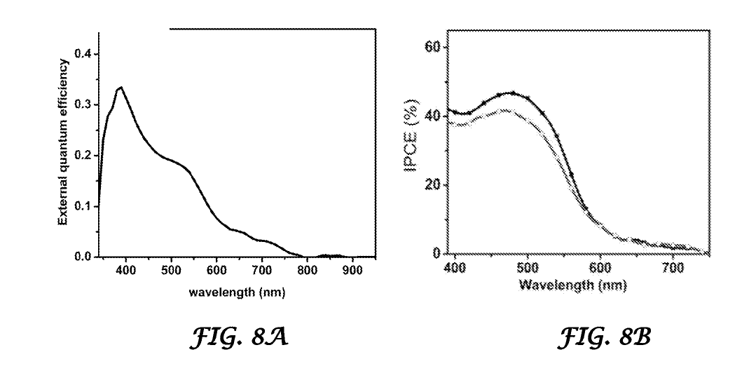

The inventors further fabricated a proof-of-concept OPV device by co-doping P1 in a standard polymer/fullerene matrix commonly used in a bulk heterojunction device structure. The data, shown in FIG. 8, verified photocurrent generation in UV/Vis/NIR regions where only P1 absorbs while the polymer/fullerene matrix components do not. The action spectrum of this device (FIG. 8) shows peaks that are more similar to those for P1 in solution (FIGS. 3A and 3B and FIG. 7) than those for the solid form (FIG. 1A). While this device demonstrates successful use of one of the embodiment materials of this invention in OPVs, improved device structures and device architecture (vide infra) will take advantage of the entire solid-state absorption of P1 and other embodiments. A detailed description of the preferred active materials and devices follows.

I. Photovoltaic Materials: Metal-Organic “Black Absorbers”: The active photovoltaic materials to be investigated belong to the following small-molecule systems:

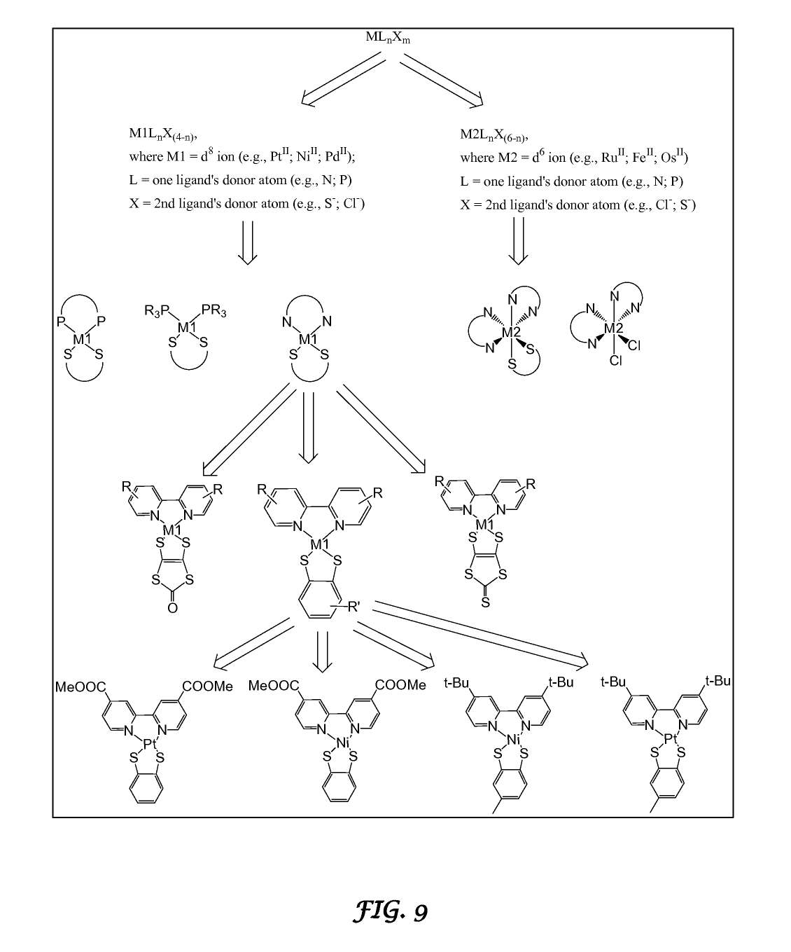

Mixed-Ligand Metal-Organic Complexes: A hierarchy of the chemical structures of the embodiments is shown in FIG. 9. In general, these embodiments are neutral transition metal complexes containing two dissimilar ligands coordinating to the metal center. Some complexes, including P1 and R1 discussed above, contain both electron-donating (e.g., thiolate) and electron-accepting (e.g., imine) ligands and are thus considered ambipolar, which is a desired characteristic for carrier transport. The metal ions have d⁸ or d⁶ electronic configuration including both heavy (e.g., Pt^{II} and Ru^{II}) and light (e.g., Ni^{II} and Fe^{II}) transition metal ions. The latter offer significant economic and practical advantages due to the approximately three-order-of-magnitude price difference as well as abundance in earth versus their former heavier congeners. Our spectroscopic and theoretical investigations suggested a primarily inter-ligand charge transfer transition being responsible for the low-energy absorptions of these materials, which renders similarity in the electronic structure between the heavier and lighter congeners. appropriate design, as demonstrated for P1 and R1 in FIG. 1B, these ambipolar solids exhibits strong, continuous absorptions that span the accessible UV region (due to ligand-centered ππ* transitions) and the entire visible region (due to interligand charge transfer and intermolecular aggregation).

Binary Donor-Acceptor Adducts: The above ambipolar complexes can form binary adducts with organic and metal-organic donors and acceptors. The P2 black absorber complex represented in FIG. 1B is an example of a binary adduct made by reacting or co-depositing a d⁸ ambipolar complex similar to P1 and an organic fluorenone-based acceptor. The inventors also isolated similar binary adducts with quinone-based acceptors (Chen et al., 2006; Smucker et al., 2003). However, the donor-to-acceptor charge transfer (DACT) bands are weak in the solid binary adducts with quinone-based acceptors, similar to analogous adducts reported in the literature for metal phthalocyanines such as CuPc (Chen et al., 2006; Smucker et al., 2003). In contrast, much stronger DACT bands are exhibited by binary adducts of the embodiment ambipolar complexes with larger, more conjugated organic acceptors based on fluorenone, perylene, and fullerene, as manifested by the lower-energy absorption that peaks at ˜1050 nm for P2 (FIG. 1B). Thus, the present invention focuses on devices in which the metal-organic embodiments are paired with such conjugated organic acceptors, including commercially-available acceptors (e.g., C₆₀ derivatives; PTCBI=3,4,9,10-perylenetetracarboxylic bis-benzimidazole) as well as other synthetic novel macromolecular conjugated organic and metal-organic acceptors. A major advantage of such binary donor-acceptor adducts is higher quantum efficiency of charge carrier generation under light exposure, which occurs not only in the spectral region of the donor absorption alone but also that of the D⁺ donor cation, A⁻ acceptor anion, and their D⁺A⁻ charge transfer complex. On appropriate design, as demonstrated for P2 in FIG. 1B and several other examples not shown, these DACT absorptions usually lie in the NIR region to extend the continuous UV/Vis absorption range of the donor complex alone.

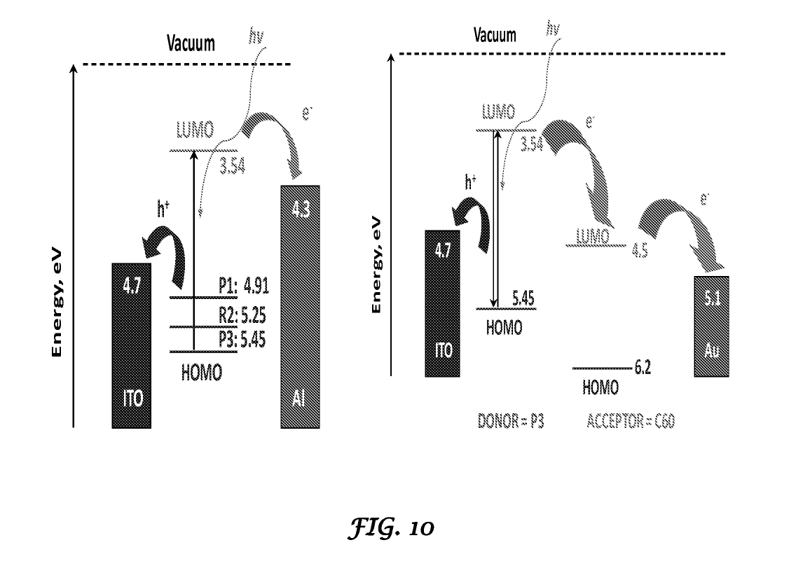

II. Photovoltaic Devices: A variety of conventional thin-film device structures can be fabricated from the preferred embodiments of this work, including: (a) single-layer Schottky-barrier devices with the active ambipolar material; (b) bulk heterojunction devices with typical acceptors such as fullerenes; (c) p-n junction devices that utilize the metal complex small molecule or metallopolymer as the p-type material and an organic or inorganic (such as ZnO) acceptor as the n-type material; and (d) more sophisticated multi-layer heterojunction structures and tandem cells. Two examples are shown in FIG. 10 for the aforementioned device types (a) and (c) utilizing the active photovoltaic materials discussed above. In all these examples, electron and hole transport is exothermic and should proceed without an electrical barrier. Therefore, charge separation is achieved easily upon photon absorption. The spectral and electrochemical data for some of the materials available allow intuitive design of several of these device structures (FIG. 10) while further optimization of carrier transport and charge separation can be achieved by known strategies (Thompson and Frechet, 2008; Peumans et al., 2003).

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

### REFERENCES

U.S. Pat. No. 6,657,378: Organic photovoltaic devices.
U.S. Pat. No. 6,051,702: Organic dyes for photovoltaic cells and for photoconductive electrophotography systems.
United States Patent Application No. 20090133752: Organic photovoltaic device with improved power conversion efficiency and method of manufacturing same.
Thompson, B. C.; Frechet, J. M. J. Angew. Chem. Int. Ed. 2008, 47, 58.
Peumans, P.; Yakimov, A.; Forrest, S. R. J. Appl. Phys. 2003, 93, 3693.
Chen, W.-H.; Reinheimer, E. W.; Dunbar, K. R.; Omary, M. A. Inorg. Chem. 2006, 45, 2770.
Smucker, B. W.; Hudson, J. M.; Omary, M. A.; Dunbar, K. R. Inorg. Chem. 2003, 42, 4714.

1-49. (canceled)

50. A sensitizer for solid-state organic photovoltaic devices comprising
a mixed ligand metal-organic complex of formula (I): 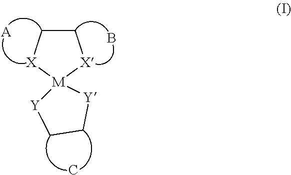
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
A is a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous;
B is a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous; and
C is an aromatic ring, a substituted benzene, a phenyl group, a keto group, a thioamide group, or a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous.

51. The complex of claim 50, wherein the complex comprises Ru(phen)₂(bdt), wherein phen=1,10-phenanthroline and bdt=1,2-benzenedithiolate; Pt(dmecbpy)(bdt), wherein dmecbpy=4,4′-di-methoxyester-2,2′-bipyridine and bdt=1,2-benzenedithiolate; or {Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone.

52. The complex of claim 50, wherein the complex comprises the complex of formula (II): 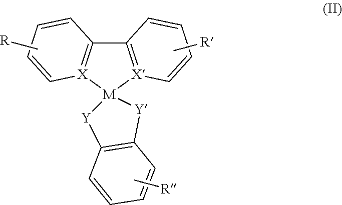
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
R is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group;
R′ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and
R″ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group.

53. The complex of claim 50, wherein the complex comprises the complex of formula (III): 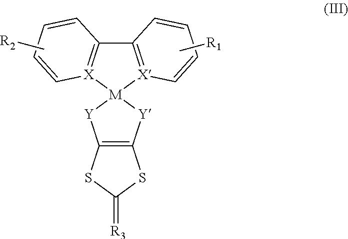
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
R₁ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group;
R₂ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and
R₃ is independently selected from a carbon, an oxygen, a nitrogen, or a sulfur.

54. The complex of claim 50, wherein the complex comprises the complex of formula 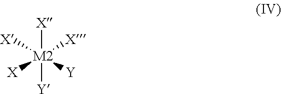
wherein,
M2 is a metal with a d⁶ electronic configuration selected from a group consisting of Fe, Ru, Os, Co, Rh, Ir, Pt, Pd, and Ni;
X, X, X′, and X′″ are one or more neutral ligand donor atoms, selected from a group consisting of N, P, As, and Sb; and
Y and Y′ are one or more anionic ligand donor atoms selected from a group consisting of S, Cl, O, F, and Br.

55. The complex of claim 50, wherein the complex comprises the complex of formula (V):

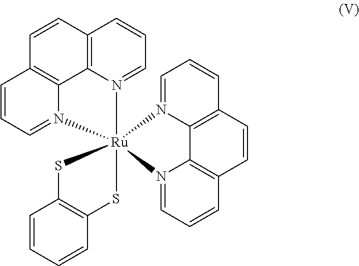

56. The complex of claim 50, wherein the complex absorbs an ultraviolet radiation, a visible radiation, and a near-infrared radiation and is contained in an organic heterojunction separating an anode and a cathode of a multi-layer organic photovoltaic (OPV) device, wherein the heterojunction comprises an electron donor layer, in contact with an electron acceptor layer.

57. The complex of claim 50, wherein the complex comprises the complex of formula (VI):

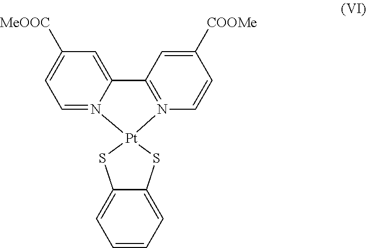

58. The complex of claim 50, wherein the complex comprises the complex of formula (VII):

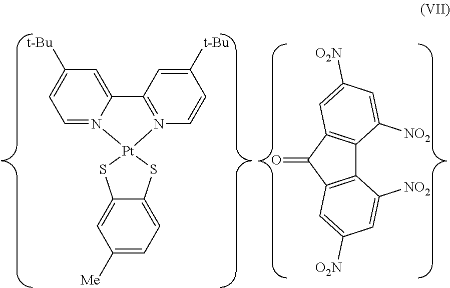

59. An organic photovoltaic device comprising:
an anode;
a cathode; and
an organic heterojunction separating the anode and the cathode, wherein the heterojunction comprises a single layer or multiple layers of an electron donor layer, in contact with an electron acceptor layer, wherein the organic heterojunction comprises a mixed ligand metal-organic complex of formula (I): 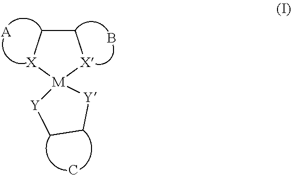
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
A is a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous;
B is a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous; and
C is an aromatic ring, a substituted benzene, a phenyl group, a keto group, a thioamide group, or a heterocyclic ring structure selected from a group consisting of a 3-membered, 4-membered, 5-membered, 6-membered, and 7-membered heterocyclic compounds, wherein the heterocyclic compounds comprise one or more hetero atoms selected from a group consisting of nitrogen, oxygen, sulfur, arsenic and phosphorous.

60. The device of claim 59, wherein the anode comprises, metals, alloys, ITO, conducting polymers, or any combinations thereof and the cathode comprises metals selected from a group consisting of Au, Ag, Fe, Al, Mg, Mn, Ni, and Ca.

61. The device of claim 59, wherein the complex comprises Ru(phen)₂(bdt), wherein phen=1,10-phenanthroline and bdt=1,2-benzenedithiolate; Pt(dmecbpy)(bdt), wherein dmecbpy=4,4′-di-methoxyester-2,2′-bipyridine and bdt=1,2-benzenedithiolate; or {Pt(dbbpy)(tdt)}{TENF}, wherein dbbpy=4,4′-di-tert-butyl-2,2′-bipyridine, tdt=3,4-toluenedithiolate and TENF=2,4,5,7-tetranitro-9-fluorenone.

62. The device of claim 59, wherein the mixed ligand metal-organic complex comprises the organic complex of formula (II): 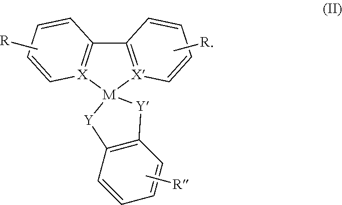
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
R is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group;
R′ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and
R″ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group.

63. The device of claim 59, wherein the mixed ligand metal-organic complex comprises the organic complex of formula (III): 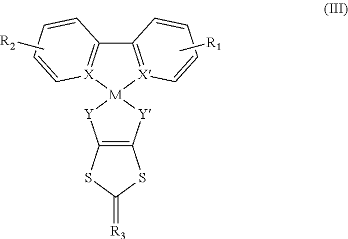
wherein,
M is a metal with a d⁸ electronic configuration selected from a group consisting of Pt, Pd, Ni, Fe, Ru, Os, Co, Rh, and Ir;
X and X′ are one or more first ligand donor atoms, selected from a group consisting of N, P, As, and Sb;
Y and Y′ are one or more second ligand donor atom selected from a group consisting of S, Cl, O, F, and Br;
R₁ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group;
R₂ is independently selected from a group consisting of a hydrogen, a methyl group, an ethyl group, a t-butyl group, a —COOCH₃ group, a C₁-C₆ Alkyl, a C₁-C₆ Alkenyl, a halo, a substituted C₁-C₆ alkyl, a substituted C₁-C₆ alkenyl, a carbonyl, a carbonate ester, an acetoxy group, an acetyl group, an ether, an ester, an alkyl alkanoate group, an alkoxy group, a keto group, and an oxo group; and
R₃ is independently selected from a carbon, an oxygen, a nitrogen, or a sulfur.

64. The device of claim 59, wherein the mixed ligand metal-organic complex comprises the organic complex of formula (IV): 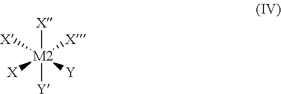
wherein,
M2 is a metal with a d⁶ electronic configuration selected from a group consisting of, Fe, Ru, Os, Co, Rh, Ir Pt, Pd, and Ni;
X, X, X′, and X′″ are one or more neutral ligand donor atoms, selected from a group consisting of N, P, As, and Sb; and
Y and Y′ are one, or more anionic ligand donor atoms selected from a group consisting of S, Cl, O, F, and Br.

65. The device of claim 59, wherein the mixed ligand metal-organic complex comprises the organic complex of formula (V):

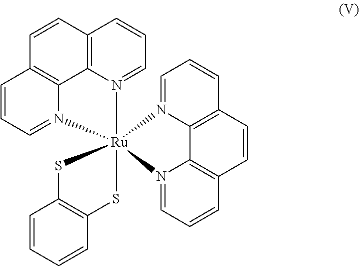

66. The device of claim 59, wherein the mixed ligand metal-organic complex comprises the organic complex of formula (VI):

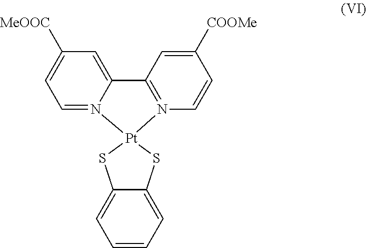

67. The device of claim 59, wherein the mixed ligand metal-organic complex comprises the organic complex of formula (VII): [chemical structure]
